(19) United States
(12) Patent Application Publication
(10) Pub. No.: US 2019/0211472 A1
(43) Pub. Date: Jul. 11, 2019

(54) Silicon Carbide Single Crystal Manufacturing Device

(71) Applicants: Lenian ZHANG, Taizhou City, Zhejiang Province (CN); TAIZHOU BEYOND TECHNOLOGY CO., LTD., Taizhou City, Zhejiang Province (CN)

(72) Inventors: Masahiro HOSHINO, Kawaguchi, Saitama (JP); Lenian ZHANG, Taizhou City, Zhejiang Province (CN)

(73) Assignees: Taizhou Beyond Technology Co., Ltd., Taizhou City, Zhejiang Province (CN); Lenian Zhang, Taizhou City, Zhejiang Province (CN)

(21) Appl. No.: 16/328,289

(22) PCT Filed: Aug. 14, 2017
(86) PCT No.: PCT/CN2017/097309

§ 371 Date: Feb. 26, 2019

(30) Foreign Application Priority Data
Aug. 31, 2016 (CN) 201610796440.1

(51) Int. Cl. C30B 23/00; C30B 23/06; C30B 29/36

(52) U.S. Cl. CPC C30B 23/002; H01L 21/02631; C30B 29/36; C30B 23/066

(57) ABSTRACT

A silicon carbide single crystal manufacturing device comprises a furnace, a crucible disposed in the furnace, and a seed crystal holder capable of mounting seed crystals. The seed crystal holder is disposed at an upper portion of the crucible, and the seed crystal holder is capable of rotating and lifting up and down. Inside the furnace is further disposed with a furnace heater capable of heating the furnace to form an ambient first temperature gradient in the furnace. A heater-cooler device capable of acting on silicon carbide single crystals is disposed outside the seed crystal holder. The silicon carbide single crystal manufacturing device is capable of growing silicon carbide single crystals at a high speed while ensuring the high quality of the silicon carbide single crystals, thereby realizing large-diameter growth of the silicon carbide single crystals and reducing the loss in post-machining process.

### BACKGROUND OF THE INVENTION

### Field of Invention

The present invention belongs to the technical field of mechanical devices for semiconductor manufacture, and particularly relates to a silicon carbide single crystal manufacturing device.

### Related Art

The sublimation method is currently the standard method for manufacturing silicon carbide crystals. Generally, the medium-frequency induction heating method is adopted, that is, silicon carbides in a crucible are heated and sublimated, and seed crystals are further disposed above the crucible, so that gaseous silicon carbides rise and contact the seed crystals, and silicon carbide single crystals are formed after the seed crystals are condensed. It is difficult to precisely control the temperature of the crystal growth surfaces by heating the large environment in a furnace with a heater. The current method is to directly set the temperature of the crystal growth surfaces at about 2250° C., but the silicon carbide single crystals directly grown under this temperature are prone to damage in the subsequent machining process. In order to improve the quality of the silicon carbide single crystals, the only way is to reduce the growth rate, and to reduce the growth diameter. However, ensuring the quality of the silicon carbide crystals by reducing the growth rate and growth diameter will result in the high costs of the silicon carbide single crystals.

There is also a CVD method for producing silicon carbide single crystals, for example, one Chinese invention patent application discloses a device for manufacturing silicon carbide single crystals, silicon carbide single crystals are grown on seed crystals by supplying a raw material gas from below the seed crystals. The device comprises a heater-container and a base positioned in the heater-container, and the seed crystals are mounted on the base. The device further comprises a first inlet for causing a purified gas to flow along an inner wall surface of the heater-container, a purified gas source for supplying the purified gas to the first inlet, a second inlet for causing the purified gas to flow along an outer wall surface of the base, and a mechanism for supporting the base and for supplying the purified gas from an underside of the base to the base. The device is a device for producing silicon carbide single crystals by the high-temperature CVD method, the silicon carbide single crystals are produced by using a gas as a raw material such as SiH4 without using powder, where gas contamination is severe, and which process is completely different from the production of silicon carbide single crystals by a physical sublimation method.

### SUMMARY OF THE INVENTION

In view of the above problems in the prior art, an object of the present invention is to provide a silicon carbide single crystal manufacturing device, and the silicon carbide single crystal manufacturing device is capable of growing silicon carbide single crystals at a high speed while ensuring the high quality of the silicon carbide single crystals, thereby realizing large-diameter growth of the silicon carbide single crystals and reducing the loss in post-machining process.

One object of one embodiment of the present invention can be achieved by the following technical solution: a silicon carbide single crystal manufacturing device comprises a furnace, a crucible disposed in the furnace, and a seed crystal holder capable of mounting seed crystals; the seed crystal holder is disposed at an upper portion of the crucible, and the seed crystal holder is capable of rotating and lifting up and down; inside the furnace is further disposed with a furnace heater capable of heating the furnace to form an ambient first temperature gradient in the furnace; wherein a heater-cooler device capable of acting on silicon carbide single crystals is disposed outside the seed crystal holder.

One embodiment of a silicon carbide powder is placed in the crucible, and the furnace heater is capable of heating the furnace to form the ambient first temperature which is gradient-distributed along an axial direction in the furnace. The silicon carbide powder in the crucible is sublimated into a gaseous state and rises to the seed crystals under the heating of the furnace heater. The seed crystals are mounted on the seed crystal holder, lower end surfaces of the seed crystals are crystal growth surfaces, and the heater-cooler device is disposed outside the seed crystal holder and forms major temperature influence factors on the seed crystals. A cooling temperature lower than the temperature of the furnace can be generated at a lower end of the heater-cooler device to promote the condensation of the gaseous silicon carbides on the crystal growth surfaces into the silicon carbide crystals. As the growth of the silicon carbide single crystals is generated, the seed crystal holder rotates upward and rises. Due to the accelerated cooling crystallization of the crystal growth surfaces by the heater-cooler device, concave or convex irregular crystallized surfaces are generated on the crystal growth surfaces, or needle-like surfaces or capillary pores are grown on the crystal growth surfaces, leading to situations where accelerated cooling yields poor crystallization and mechanical efficiency. At this time, the heater-cooler device heats the unfavorable crystallized surfaces at a silicon carbide sublimation temperature higher than the temperature of the furnace, so that the unfavorable crystallized surfaces are vaporized and sublimated and restored to relatively flat crystallized growth surfaces, thereby ensuring the quality of the silicon carbide single crystals, that is, reducing the loss in subsequent machining process, and then followed by rapid cooling, thus a cooling and heating cycle is carried out to achieve the effects of fast crystal growth while maintaining excellent mechanical performance.

In one embodiment of the above-mentioned silicon carbide single crystal manufacturing device, the heater-cooler device is capable of forming a second temperature gradient distributed along an axial growth direction of the silicon carbide single crystals. Gaseous silicon carbides can condense on the crystal growth surfaces and gradually condense into a column. A direction of the column is the axial growth direction of the single crystals, and inside the heater-cooler device there is a temperature gradient distributed along the axial growth direction of the silicon carbide single crystals. The second temperature gradient can reduce an internal stress of the generated silicon carbide single crystals after cooling, and reduce the loss in subsequent machining process, that is, cracking and damage during cutting and polishing.

In one embodiment of the above-mentioned silicon carbide single crystal manufacturing device, the heater-cooler device is an induction heating coil with a frequency of 10 kHz to 50 kHz, the heater-cooler device having spirally disposed metal tubes, and the seed crystal holder capable of passing through the metal tubes as it is ascending. The spirally disposed metal tubes carry medium-high frequency current for heating. When the temperature needs to be reduced, a cooling medium is introduced into the metal tubes to make a temperature of the growth region of the silicon carbide single crystals lower than the ambient temperature in the furnace. The cooling medium can be a conventional medium such as an inert gas of argon, and a flow rate of the cooling medium can form temperature intervals of gradient distribution.

In one embodiment of the above-mentioned silicon carbide single crystal manufacturing device, the second temperature gradient formed by the heater-cooler device along an axial growth direction of the crystals is increased or decreased within a range of 1° C./mm to 20° C./mm. The second temperature gradient can reduce the stress inside the generated silicon carbide single crystals and reduce the loss of the silicon carbide single crystals in subsequent machining process.

In one embodiment of the above-mentioned silicon carbide single crystal manufacturing device, a distance d between a lower end of the heater-cooler device and a port of the crucible is equal to or greater than 20 cm. A distance between the crystal growth surfaces and the port of the crucible has a great influence on the quality of the silicon carbide single crystals. The change of the distance has a complicated relationship with factors such as particle size distribution of raw material, shape difference, crystal growth rate, and flow rate of the gaseous silicon carbides, and these factors interact with one another. In the case where the seed crystal holder rotation speed and the flow rate of the gaseous silicon carbides are set, if the distance between the crystal growth surfaces and the port of the crucible is too small, it will result in the incompletely vaporized silicon carbide powder being brought to the crystal growth surfaces, the growth rate of the silicon carbide single crystals being too fast, and also lead to a decline in the quality of the silicon carbide single crystals. Conversely, in the case where the seed crystal holder rotation speed and the flow rate of the gaseous silicon carbides are set, if the distance between the crystal growth surfaces and the port of the crucible is greater than 60 cm, it will result in a concentration of the gaseous silicon carbides at the crystal growth surfaces being too low, and the growth rate of the silicon carbide single crystals being too slow. Therefore, in order to obtain high-quality silicon carbide single crystals fast, an ideal distance between the crystal growth surfaces and the port of the crucible is 20 cm to 60 cm.

In one embodiment of the above-mentioned silicon carbide single crystal manufacturing device, the silicon carbide single crystal manufacturing device further comprises a parameter controller capable of reducing a temperature difference between a central portion and a surrounding portion of the seed crystals or the grown silicon carbide crystals. The parameter controller is capable of setting a rotation speed and a lifting speed of the seed crystal holder and is capable of setting a flow rate of the gaseous silicon carbides at the lower end of the heater-cooler device to cause growth surfaces of the silicon carbide single crystals to form a radial third temperature gradient. The radial third temperature gradient is increased or decreased by 1° C./mm to 20° C./mm. The silicon carbide single crystals are formed into a column after condensation. In the subsequent machining, the column is sliced into wafers along the radial direction, and then the extended wafers are cut laterally and vertically to form chips. Wherein if the temperature difference between the central portion and the surrounding portion of the silicon carbide crystals is large during the growth, a large radial stress will be generated inside the silicon carbide single crystals, and the stress may cause the wafers to be easily damaged during the post-machining process of the silicon carbide crystals. For this reason, the manufacturing device is provided with the parameter controller, and the parameter controller is used to reduce the temperature difference between the central portion and the surrounding portion of the silicon carbide crystals. Specifically, the parameter controller controls the temperature difference by controlling the rotation speed and the lifting speed of the seed crystal holder as well as the flow rate of the gaseous silicon carbides. Properly controlled, the rotation speed of the seed crystal holder enables the crystal growth surfaces be heated uniformly; the lifting speed of the seed crystal holder and the flow rate of the gaseous silicon carbides affect the concentration of the gaseous silicon carbides at the crystal growth surfaces, and all of these are factors that affect the temperature difference between the central portion and the surrounding portion of the silicon carbide crystals.

In one embodiment of the above-mentioned silicon carbide single crystal manufacturing device, a minimum opening area of the crucible is smaller than a half of a cross-sectional area of an inner cavity of the crucible, and an aspect ratio of a height of the crucible to a diameter of the crucible is greater than 5:1. The traditional crucible ports are relatively larger, the rising gaseous silicon carbides are diffused in the furnace, with the crystal growth surfaces occupying only a small portion of the area therein, so it is difficult to precisely control the concentration of the gaseous silicon carbides at the crystal growth surfaces, and the concentration is thin. While the port area of the crucible of the present invention is relatively smaller, smaller than a half of the cross-sectional area of the inner cavity of the crucible, so that the gaseous silicon carbides have a faster flow rate and then the concentration is increased. Therefore, the ascending gaseous silicon carbides can directly flow toward the crystal growth surfaces, which facilitates precise control of the concentration of the gaseous silicon carbides at the crystal growth surfaces; thereby ensuring the quality of the silicon carbide crystals, increasing the growth rate of the crystals, and a ratio of the height of the crucible to the diameter of the crucible being greater than 5:1 can also be increased to allow the powder in the crucible to be vaporized within a sufficient period of time.

In one embodiment of the above-mentioned silicon carbide single crystal manufacturing device, the present silicon carbide single crystal manufacturing device further comprises a temperature controller capable of controlling a first temperature gradient formed by the furnace heater, and the temperature controller is capable of controlling a corresponding temperature of the furnace heater when assuaging the silicon carbide crystal transformation, so that a temperature dropping rate is between 0.5° C./min and 30° C./min. The manufacturing device is provided with the temperature controller capable of sensing temperature fluctuations in the first temperature gradient interval, thereby timely controlling the temperature adjustment of the furnace heater, and improving the quality of the silicon carbide crystals. With cooling and annealing after condensation of the silicon carbide single crystals, the crystal form of the silicon carbide single crystals will undergo a corresponding transformation. For example, the crystal structure is a 15R rhombohedral symmetrical structure when the interval is 2200° C., the crystal structure is 6H hexagonal crystal when the interval is 1900° C., the crystal structure is 4H cubic crystal when the interval is 1700° C., and the crystal structure is 3C cubic crystal when the crystals are condensed at 1500° C. However, the transformation of the silicon carbide single crystals brings about stresses, which cause distortion among different crystal forms, and other adverse factors affecting the quality of the silicon carbide single crystals. Therefore, the temperature controller controls the furnace heater to generate a suitable first temperature gradient, and the ambient temperature with gradient changes can assuage the temperature dropping rate, thereby eliminating the stresses generated during the silicon carbide single crystal transformation, and improving the quality of the silicon carbide single crystals, wherein one or more than one of the furnace heaters are provided to heat different parts of the furnace as needed.

In one embodiment of the above-mentioned silicon carbide single crystal manufacturing device, an inner bottom surface of the crucible is connected with a plurality of jet pipes, at an upper end of each of the jet pipes is an umbrella-shaped dustproof part, an outer wall of the jet pipe has a plurality of downwardly inclined branch tubes, the branch tubes are located below the dustproof part, and a lower end port of each of the branch tubes is a nozzle, and the jet pipes communicate with a gas source. The gas source is capable of supplying gas to the jet pipes, so that the gas is ejected from the nozzles of the branch tubes. The nozzles of the branch tubes are inclined downwardly, so that the ejected gas can make the silicon carbide powder or fine particles deposited on the bottom surface of the crucible to fly and float. The flying and floating silicon carbide powder or fine particles can be heated and sublimated more uniformly and efficiently to enhance the sublimation efficiency. Only by ensuring the generation efficiency of the gaseous silicon carbides can a basis be provided for controlling the flow rate and concentration of the gaseous silicon carbides, wherein the dustproof parts can prevent the silicon carbide powder or the silicon carbide fine particles from blocking the nozzles of the branch tubes to ensure the stability of the mechanical structure.

In one embodiment of the above-mentioned silicon carbide single crystal manufacturing device, the furnace is disposed with a preheat canister below the crucible, below the preheat canister is disposed with a heat source capable of heating a bottom of the preheat canister, lower ends of the jet pipes extend outside a bottom surface of the crucible and extend into the preheat canister, and the preheat canister communicates with the gas source. The preheat canister is heated by the heat source, when the gas of the gas source passes through the preheat canister, it can be heated to a set temperature, and when the gas with the set temperature enters the crucible, the silicon carbide powder or the fine particles can be heated to improve the sublimation efficiency.

In one embodiment of the above-mentioned silicon carbide single crystal manufacturing device, a plurality of vapor chambers are horizontally and fixedly connected in the preheat canister in the axial direction, a preheat channel is formed between the vapor chambers capable of allowing roundabout flowing of gas, an inlet end of the preheat channel is located at the bottom of the preheat canister, and an outlet end of the preheat channel is located at a top of the preheat canister. The gas entering from the gas source needs to flow along the preheat channel to the crucible, and the preheat channel is disposed in a roundabout manner, which can fully utilize a limited space of the preheat canister and fully utilize a limited quantity of the vapor chambers, thereby increasing a circulation time of the gas in the preheat canister, so that the gas is heated sufficiently.

In one embodiment of the above-mentioned silicon carbide single crystal manufacturing device, an edge of each of the vapor chambers is disposed with a gas gap, the gas gaps at the two adjacent vapor chambers are respectively located on two opposite sides of an axis of the preheat canister, the gas source communicates with a bottom of an inner cavity of the preheat canister through a gas supply tube, and the jet pipes communicate with a top of the inner cavity of the preheat canister. The gas flows from the bottom to the top of the inner cavity of the preheat canister, and the gas flows radially when it flows from one of the gas gaps to the adjacent gas gap, thus increasing a travel distance of the gas.

In one embodiment of the above-mentioned silicon carbide single crystal manufacturing device, the gas source comprises a plurality of gas storage tanks, and there is a plurality of the gas supply tubes, first ends of the gas supply tubes extend into the furnace and communicate with the preheat canister, and second ends communicate with the gas storage tanks respectively. The gas input into the preheat canister through the gas supply tubes can be one or more of H2, AR, HCL, Air, C3H8, CH4, C2H6, so a plurality of the gas storage tanks are preset for storing the above plurality of gases, and the gas storage tanks communicate with the preheat canister through the respective gas supply tubes, so that one or more types of the gases can be input into the preheat canister.

In one embodiment of the above-mentioned silicon carbide single crystal manufacturing device, the seed crystal holder has a disk shape, a lower end surface of the seed crystal holder is disposed with a mounting groove capable of mounting the seed crystals, and an upper end surface of the seed crystal holder is shaped as a flat bottom cavity or a downwardly curved concave or an upwardly curved convex. The seed crystal holder is capable of absorbing the heat in the ambient environment and transferring it to the silicon carbide single crystals fast. When the upper end surface of the seed crystal holder is downwardly curved concave, heat transfer in thick positions of the seed crystal holder is slower, and heat transfer in thin positions of the seed crystal holder is faster. Since the thermal conductivity of the silicon carbide single crystals is very good, the shape of the seed crystal holder affects a radial third temperature gradient on the grown silicon carbide single crystals during the growth of the silicon carbide single crystals. With the disposition of the above-mentioned parameter controller, and heating outsides of the grown silicon carbide single crystals by the heater-cooler device, so that the temperature gradient of the crystallized surfaces is maintained to increase or decrease within a range of 1° C./mm to 20° C./mm. When the upper end surface of the seed crystal holder is an upwardly curved convex, a thickness of a center position of the seed crystal holder is greater than that of a surrounding area, resulting in a temperature of the outsides of the silicon carbide single crystals being larger than a temperature of the central position. At this time, an external air flow of the silicon carbide single crystals can be increased by increasing the rotation speed of the seed crystal holder, thereby reducing the temperature difference between the central portion and the surrounding portion of the silicon carbide single crystals, so that the temperature gradient of the crystallized surfaces is maintained to increase or decrease within a range of 1° C./mm to 20° C./mm.

In one embodiment of the above-mentioned silicon carbide single crystal manufacturing device, an upper end of the furnace is rotatably connected with a lifting shaft, a lower end of the lifting shaft extends into the furnace, the seed crystal holder is mounted at the lower end of the lifting shaft, and an upper end of the lifting shaft is respectively connected with a motor capable of driving the lifting shaft to rotate and a first cylinder capable of driving the lifting shaft to lift up and down. That is, the seed crystal holder is lifted and lowered by the first cylinder, and is rotated by the motor, which are ordinary mechanical transmission structures. The manufacturing device adopts an integrated magnetic fluid seal transmission device to simplify the above structures.

In one embodiment of the above-mentioned silicon carbide single crystal manufacturing device, the furnace heater comprises a first induction heating coil capable of heating the preheat canister, a second induction heating coil capable of heating the silicon carbide powder in the crucible, a third induction heating coil capable of heating a region between the lower end of the heater-cooler device and the port of the crucible, and a fourth induction heating coil capable of heating an upper portion of the furnace where the heater-cooler device is located. The first induction heating coil heats the preheat canister to optimize a temperature of the gas entering the crucible, and further preheats the silicon carbide powder or fine particles. The second induction heating coil heats the crucible to rapidly sublimate the silicon carbide powder floating in the crucible. The third induction heating coil is capable of maintaining the silicon carbides flowing out of the crucible in a gaseous state, and at the same time sublimating the un-sublimated silicon carbide powder flowing out with the airflow to ensure that no powder impurities enter the crystal growth surfaces. The fourth induction heating coil is capable of providing an ambient temperature for the heater-cooler device, and then precisely controlling the temperature gradient interval by the heater-cooler device.

In one embodiment of the above-mentioned silicon carbide single crystal manufacturing device, the heater-cooler device is connected to an adjust shaft, and the furnace is disposed with a second cylinder capable of driving the adjust shaft to lift up and down. It is also an ordinary existing lifting structure for driving the heater-cooler device to lift up and down by the second cylinder.

Compared with the prior art, one embodiment of the silicon carbide single crystal manufacturing device has the following advantages:

1. As the silicon carbide single crystals grow, the seed crystal holder rotates upward and rises, and the heater-cooler device is capable of forming the second temperature gradient distributed along the axial growth direction of the silicon carbide single crystals, and the second temperature gradient can reduce a stress of the generated silicon carbide single crystals, and reduce the loss in subsequent machining process.

2. Due to the accelerated cooling crystallization of the crystal growth surfaces by the heater-cooler device, concave or convex irregular crystallized surfaces are generated on the crystal growth surfaces, or needle-like surfaces are grown on the crystal growth surfaces, and the heater-cooler device heats the unfavorable crystallized surfaces with the silicon carbide sublimation temperature higher than the temperature of the furnace, so that the unfavorable crystallized surfaces are vaporized and sublimated again and restored to relatively flat crystallized growth surfaces, thereby ensuring the crystallized quality of the silicon carbide single crystals, and then followed by rapid cooling, thus a cooling and heating cycle is carried out to achieve the effects of fast crystal growth while maintaining excellent mechanical performance, and large-diameter growth of the silicon carbide single crystals can be realized.

3. Since the manufacturing device is provided with the parameter controller, the temperature difference between the central portion and the surrounding portion of the silicon carbide crystals can be reduced by the parameter controller, so that wafer damage can be reduced during machining.

### BRIEF DESCRIPTION OF THE DRAWINGS

FIG. 1 is a perspective view of one embodiment of a silicon carbide single crystal manufacturing device of the present invention;

FIG. 2 is a cross-sectional view of one embodiment of the state of use of the silicon carbide single crystal manufacturing device of the present invention;

FIG. 3 is an enlarged view of A in FIG. 2;

FIG. 4 is an enlarged view of B in FIG. 2;

FIG. 5 is a cross-sectional view along C-C of FIG. 2;

FIG. 6 is a cross-sectional view of the silicon carbide single crystals growing state of the first embodiment of the silicon carbide single crystal manufacturing device of the present invention;

FIG. 7 is a cross-sectional view of one embodiment of a seed crystal holder with an upwardly curved convex upper end surface;

FIG. 8 is a cross-sectional view of one embodiment of the seed crystal holder with a downwardly curved concave upper end surface; and

FIG. 9 is a cross-sectional view of one embodiment of the seed crystal holder with a flat bottom cavity at the upper end surface.

### DETAILED DESCRIPTION OF THE INVENTION

The technical solutions of the present invention are further described below with reference to the specific embodiments of the present invention in conjunction with the accompanied drawings, but the present invention is not limited to the embodiments.

### Embodiment 1

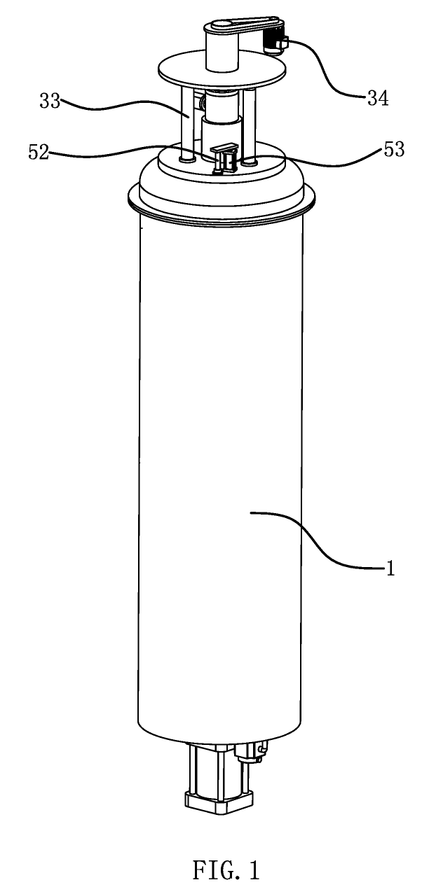

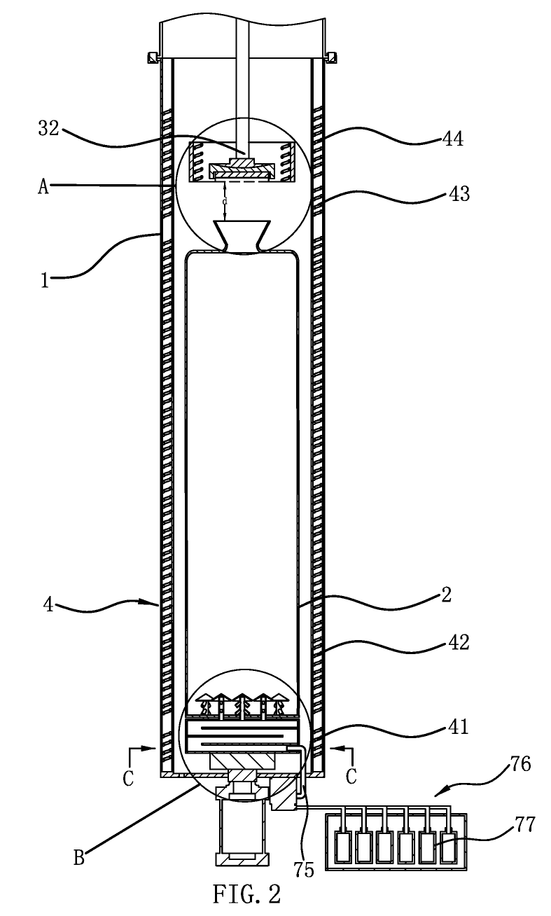

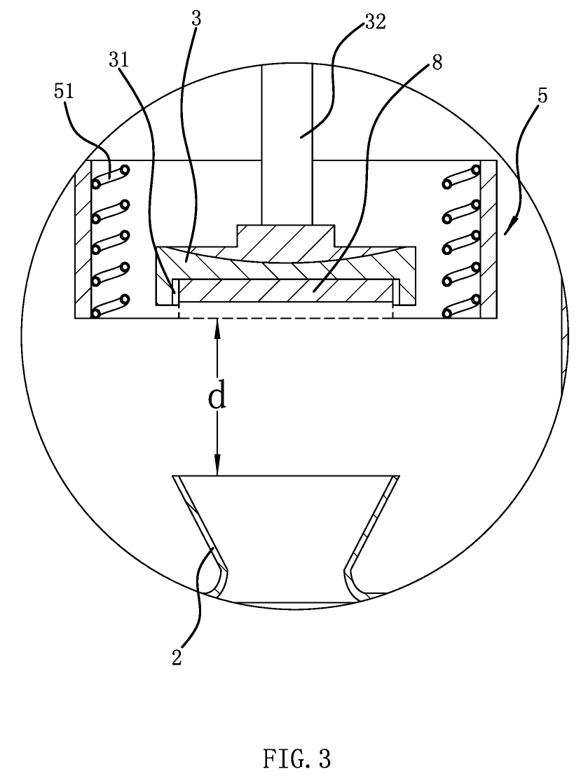

As shown in FIG. 1, FIG. 2, and FIG. 3, one embodiment of a silicon carbide single crystal manufacturing device comprises a furnace 1 and a crucible 2 disposed in the furnace 1, a silicon carbide powder is placed in the crucible 2, and a seed crystal holder 3 is disposed at an upper portion of the crucible 2. The seed crystal holder 3 is mounted with seed crystals 8, and the seed crystal holder 3 is capable of rotating and lifting up and down, that is, an upper end of the furnace 1 is rotatably connected with a lifting shaft 32, a lower end of the lifting shaft 32 is extended into the furnace 1, the seed crystal holder 3 is mounted at the lower end of the lifting shaft 32, and an upper end of the lifting shaft 32 is respectively connected with a motor 34 capable of driving the lifting shaft 32 to rotate and a first cylinder 33 capable of driving the lifting shaft 32 to lift up and down. A furnace heater 4 is further disposed in the furnace 1, and the furnace heater 4 is capable of heating the furnace 1 to form an ambient first temperature gradient in the furnace 1. A heater-cooler device 5 is disposed outside the seed crystal holder 3, the heater-cooler device 5 is in the shape of a cylinder and is fixedly connected with an adjust shaft 52. The furnace 1 is fixedly connected with a second cylinder 53, and the second cylinder 53 is connected to the adjust shaft 52 and is capable of driving the adjust shaft 52 to lift up and down. The heater-cooler device 5 is capable of acting on silicon carbide single crystals 9 and capable of forming a second temperature gradient distributed along an axial growth direction of the silicon carbide single crystals.

Specifically, one embodiment of the heater-cooler device 5 is an induction heating coil, and a frequency of the induction heating coil is 10 kHz to 50 kHz. The induction heating coil with a frequency of 30 kHz adopted in this embodiment has better effects, the induction heating coil comprises spirally disposed metal tubes 51, metal tubes 51 form the induction heating coil made of electrical conductive material, such as copper, aluminum and other electrical conductive metal, and the seed crystal holder 3 is capable of passing through the metal tubes 51 as it is ascending. The second temperature gradient formed by the heater-cooler device 5 along the axial growth direction of the crystals is increased or decreased within a range of 1° C./mm to 20° C./mm. In this embodiment, the second temperature gradient formed by the heater-cooler device 5 along the axial growth direction of the crystals is increased or decreased at 10° C./mm, and the second temperature gradient can reduce a stress of the generated silicon carbide single crystals and increase the efficiency of machining. The silicon carbide single crystal manufacturing device further comprises a parameter controller capable of reducing a temperature difference between a central portion and a surrounding portion of the seed crystals 8. The parameter controller is capable of setting a rotation speed and a lifting speed of the seed crystal holder 3 and is capable of setting a flow rate of the gaseous silicon carbides at the lower end of the heater-cooler device 5 to cause growth surfaces of the silicon carbide single crystals to form a radial third temperature gradient. A minimum opening area of the crucible 2 is smaller than a half of a cross-sectional area of an inner cavity of the crucible 2, and a ratio of a height of the crucible 2 to a diameter of the crucible 2 is equal to or greater than 5:1. In this embodiment, the crucible 2 with a ratio of the height to the diameter of 5:1 is selected. The silicon carbide single crystal manufacturing device further comprises a temperature controller capable of controlling a first temperature gradient formed by the furnace heater 4. The temperature controller is capable of controlling a corresponding temperature of the furnace heater 4 when assuaging the silicon carbide crystal transformation, so that a temperature dropping rate is between 0.5° C./min and 30° C./min.

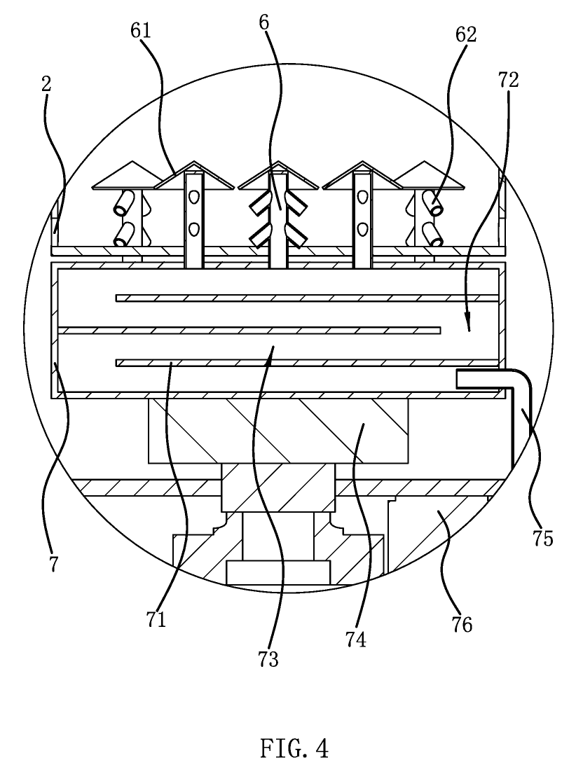

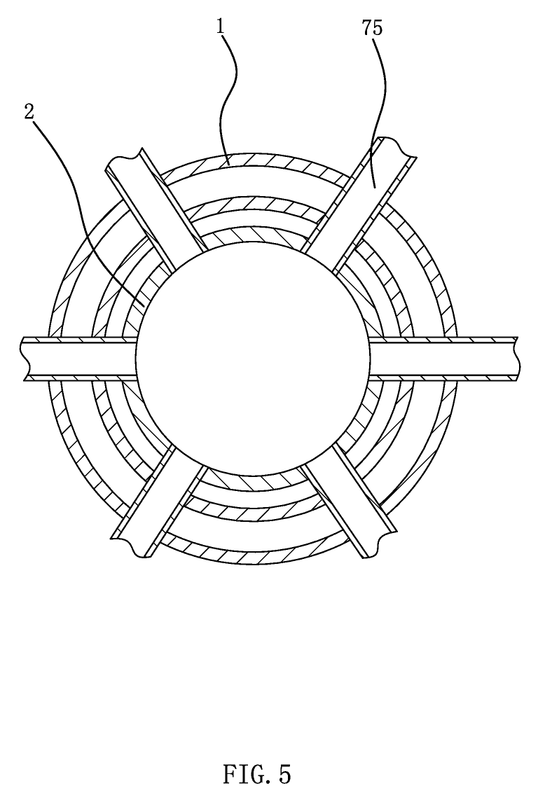

As shown in FIG. 4 and FIG. 5, an inner bottom surface of one embodiment of the crucible 2 is rotatably connected with a plurality of jet pipes 6, at an upper end of each of the jet pipes 6 is an umbrella-shaped dustproof part 61, an outer wall of the jet pipe 6 has a plurality of downwardly inclined branch tubes 62, the branch tubes 62 are located below the dustproof part 61, and a lower end port of each of the branch tubes 62 is a nozzle. The furnace 1 is disposed with a preheat canister 7 below the crucible 2, below the preheat canister 7 is disposed with a heat source 74 capable of heating a bottom of the preheat canister 7, lower ends of the jet pipes 6 extend outside a bottom surface of the crucible 2 and extend into the preheat canister 7. A plurality of vapor chambers 71 are horizontally and fixedly connected in the preheat canister 7 in the axial direction, a preheat channel 73 is formed between the vapor chambers 71 capable of allowing roundabout flowing of gas, an inlet end of the preheat channel 73 is located at the bottom of the preheat canister 7, and an outlet end of the preheat channel 73 is located at a top of the preheat canister 7. An edge of each of the vapor chambers 71 is disposed with a gas gap 72, the gas gaps 72 at the two adjacent vapor chambers 71 are respectively located on two opposite sides of an axis of the preheat canister 7, a gas source 76 communicates with a bottom of an inner cavity of the preheat canister 7 through a gas supply tube 75, and the jet pipes 6 communicate with a top of the inner cavity of the preheat canister 7. Wherein the gas source 76 comprises a plurality of gas storage tanks 77, and there is a plurality of the gas supply tubes 75, first ends of the gas supply tubes 75 extend into the furnace 1 and communicate with the preheat canister 7, and second ends communicate with the gas storage tanks 77 respectively. The gas input into the preheat canister 7 through the gas supply tubes 75 can be one or more of H2, AR, HCL, C3H8, CH4, C2H6, or air, and these gases cause the powder to float.

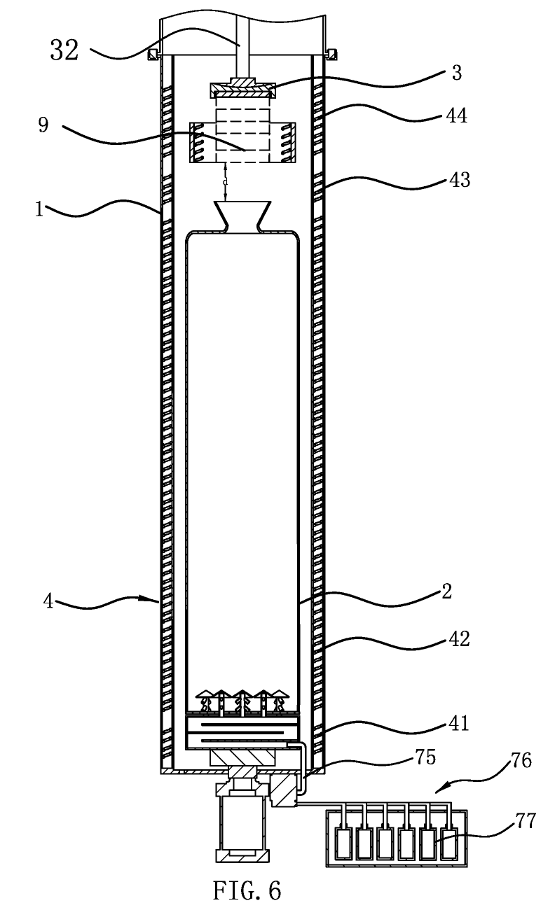

As shown in FIG. 6, one embodiment of the furnace heater 4 comprises a first induction heating coil 41 capable of heating the preheat canister 7, a second induction heating coil 42 capable of heating the silicon carbide powder in the crucible 2, a third induction heating coil 43 capable of heating a region between the lower end of the heater-cooler device 5 and the port of the crucible 2, and a fourth induction heating coil 44 capable of heating an area where the heater-cooler device 5 is located.

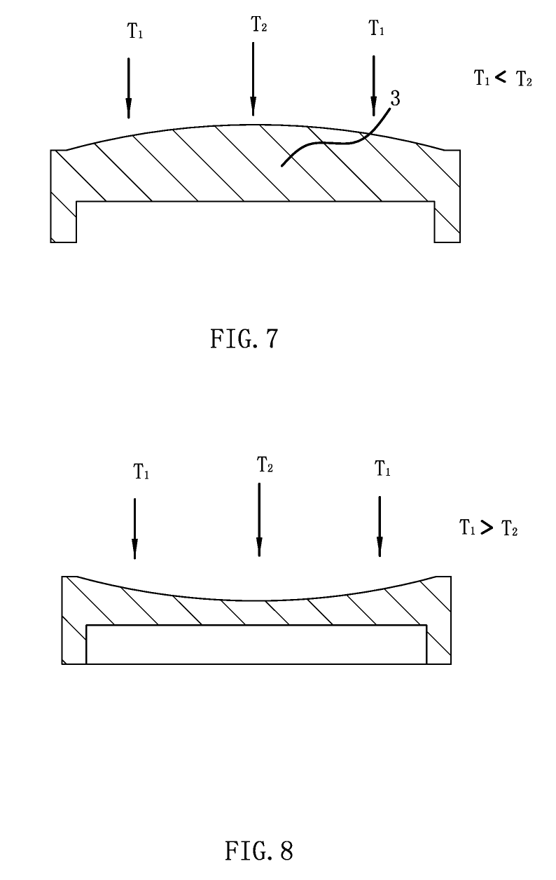

As shown in FIG. 7, one embodiment of the seed crystal holder 3 has a disk shape, a lower end surface of the seed crystal holder 3 is disposed with a mounting groove 31 capable of mounting the seed crystals 8, and an upper end surface of the seed crystal holder 3 is shaped as an upwardly curved convex. The seed crystal holder 3 is capable of absorbing the heat in the ambient environment and transferring it to the silicon carbide single crystals fast, heat transfer in thick positions of the seed crystal holder 3 is slower, and heat transfer in thin positions of the seed crystal holder 3 is faster. Since the thermal conductivity of the silicon carbide single crystals is very good, the shape of the seed crystal holder 3 generates an effect of the radial third temperature gradient on the grown silicon carbide single crystals during the growth of the silicon carbide single crystals, resulting in a temperature of the outsides of the silicon carbide single crystals being larger than a temperature of the central position. At this time, an external air flow of the silicon carbide single crystals can be increased by increasing the rotation speed of the seed crystal holder 3, thereby reducing the temperature difference between the central portion and the surrounding portion of the silicon carbide single crystals, so that the temperature gradient of the crystallized surfaces is maintained to increase or decrease within a range of 0.5° C./mm to 20° C./mm. Therefore, when the seed crystal holder 3 with the upwardly curved convex upper end surface is adopted for growing crystals, the rising speed of the seed crystal holder 3 is 0.5 mm/sec, the rotation speed of the seed crystal holder 3 is 50 rpm/min to 2000 rpm/min, and the flow rate of the gaseous silicon carbides is 1 L/min to 10 L/min, most preferably 5 L/min.

One embodiment of the furnace heater 4 is capable of heating the furnace 1 to form the ambient first temperature which is gradient-distributed along an axial direction in the furnace 1. The silicon carbide powder is placed in the crucible 2, the gas source 76 is capable of supplying the gas to the jet pipes 6, and the gas is ejected from the nozzles after passing through the preheat canister 7 and being preheated. The ejected gas can make the silicon carbide powder deposited on the bottom surface of the crucible 2 to fly and float. The silicon carbide powder in the crucible 2 is sublimated into a gaseous state and rises to the seed crystals 8 under the heating of the second induction heating coil 42. The third induction heating coil 43 is capable of maintaining the silicon carbides flowing out of the crucible 2 in a gaseous state, and at the same time sublimating the un-sublimated silicon carbide powder flowing out with the airflow to ensure the sublimation quality. The seed crystals 8 are mounted on the seed crystal holder 3, lower end surfaces of the seed crystals 8 are crystal growth surfaces, and the heater-cooler device 5 is disposed outside the seed crystal holder 3 and forms major heat source influence factors for the seed crystals 8. A cooling temperature lower than the temperature of the furnace 1 can be generated at a lower end of the heater-cooler device 5 to accelerate the condensation of silicon carbides on the crystal growth surfaces. As the growth of the silicon carbide single crystals is generated, the seed crystal holder 3 rotates upward and rises, and inside the heater-cooler device 5 is formed with the second temperature gradient distributed along the axial growth direction of the silicon carbide single crystals. The second temperature gradient can reduce an internal stress of the generated silicon carbide single crystals, and reduce the loss in subsequent machining process, that is, damage during cutting and polishing. Due to the accelerated cooling crystallization of the crystal growth surfaces by the heater-cooler device 5, concave or convex irregular crystallized surfaces are generated on the crystal growth surfaces, or needle-like surfaces or capillary pores are grown on the crystal growth surfaces, leading to situations where accelerated cooling yields poor crystallization and mechanical efficiency. At this time, the heater-cooler device 5 heats the unfavorable crystallized surfaces at a silicon carbide sublimation temperature higher than the temperature of the furnace 1, so that the unfavorable crystallized surfaces are vaporized and sublimated and restored to relatively flat crystallized growth surfaces, thereby ensuring the quality of the silicon carbide single crystals, and then followed by rapid cooling, thus a cooling and heating cycle is carried out to achieve the effects of fast crystal growth while maintaining excellent mechanical performance.

In one embodiment of the present invention, a distance between the crystal growth surfaces and the port of the crucible 2 has a great influence on the quality of the silicon carbide single crystals. The change of the distance has a complicated relationship with factors such as particle size distribution of raw material, shape difference, crystal growth rate, and flow rate of the gaseous silicon carbides, and these factors interact with one another. In order to obtain high-quality silicon carbide single crystals when the distance between the crystal growth surfaces and the port of the crucible 2 is at least it 20 cm, the following data are obtained through experiments:

Comparative example 1: the rotation speed of the seed crystal holder 3 is 1000 rpm, the rising speed of the seed crystal holder 3 is 5 mm/hour, and the flow rate of the gaseous silicon carbides is 5 L/min, the heater-cooler device 5 is not disposed, but the temperature of the crystal growth surfaces is directly maintained at 2250° C., at this time the growth rate of the silicon carbide single crystals is 20 um/hr, but the wafers are damaged during machining process.

Comparative example 2: the rotation speed of the seed crystal holder 3 is 1000 rpm, the rising speed of the seed crystal holder 3 is 5 mm/hour, the flow rate of the gaseous silicon carbides is 5 L/min, and the distance d between the crystal growth surfaces and the port of the crucible 2 is 10 cm, at this time the growth rate of the silicon carbide single crystals is 1000 um/hr, but the grown silicon carbide single crystals contain a large amount of un-sublimated materials and other impurity materials.

Comparative example 3: the rotation speed of the seed crystal holder 3 is 1000 rpm, the rising speed of the seed crystal holder 3 is 5 mm/hour, the flow rate of the gaseous silicon carbides is 5 L/min, the distance d between the crystal growth surfaces and the port of the crucible 2 is 10 cm, and the second temperature gradient formed by the heater-cooler device 5 is set within a range of 1° C./mm to 20° C./mm, at this time the damage of the wafers during machining process is remarkably reduced.

Comparative example 4: the rotation speed of the seed crystal holder 3 is 1000 rpm, the rising speed of the seed crystal holder 3 is 5 mm/hr, the flow rate of the gaseous silicon carbides is 5 L/min, the distance d between the crystal growth surfaces and the port of the crucible 2 is 20 cm ˜60 cm, and the second temperature gradient formed by the heater-cooler device 5 is set within a range of 1° C./mm to 20° C./mm, at this time the wafers are not damaged during machining process.

It can be concluded that in the case where the rotation speed of the seed crystal holder 3 and the flow rate of the gaseous silicon carbides are set, if the distance between the crystal growth surfaces and the port of the crucible 2 is too small, it will result in the incompletely vaporized silicon carbide powder being brought to the crystal growth surfaces, the growth rate of the silicon carbide single crystals being too fast, and also lead to a decline in the quality of the silicon carbide single crystals. Conversely, in the case where the rotation speed of the seed crystal holder 3 and the flow rate of the gaseous silicon carbides are set, if the distance between the crystal growth surfaces and the port of the crucible 2 is greater than 60 cm, it will result in a concentration of the gaseous silicon carbides at the crystal growth surfaces being too low, and the growth rate of the silicon carbide single crystals being too slow, and will also lead to a decline in the quality of silicon carbide single crystals. Therefore, in order to obtain high-quality silicon carbide single crystals fast, an ideal distance between the crystal growth surfaces and the port of the crucible 2 is 20 cm to 60 cm.

### Embodiment 2

The structure of the silicon carbide single crystal manufacturing device is basically the same as that of the embodiment 1, as shown in FIG. 8, the difference lies in the upper end surface of the seed crystal holder 3 being downwardly curved concave, and with the disposition of the parameter controller, and heating outsides of the grown silicon carbide single crystals by the heater-cooler device 5, so that the temperature gradient of the crystallized surfaces is maintained to increase or decrease within a range of 0.5° C./mm to 20° C./mm.

### Embodiment 3

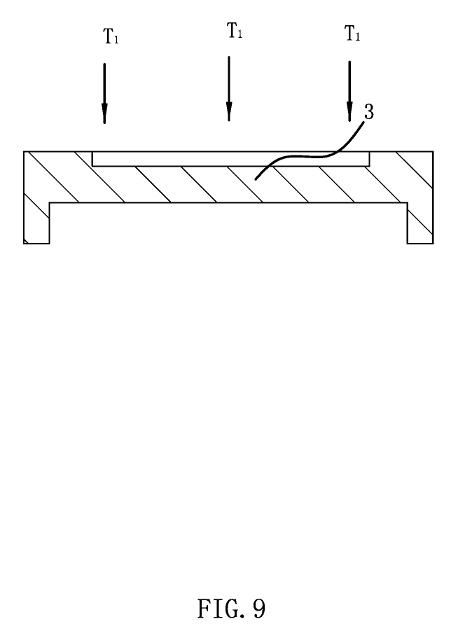

The structure of the silicon carbide single crystal manufacturing device is basically the same as that of the embodiment 1, as shown in FIG. 9, the difference lies in the upper end surface of the seed crystal holder 3 having a flat bottom cavity.

The specific embodiments described herein are merely illustrative of the spirit of the present invention. Technical personnel skilled in the art to which the present invention pertains can make various modifications or additions to the specific embodiments described or replace them in a similar manner, without departing from the spirit of the present invention or beyond the scope defined by the appended claims.

Although the terms furnace 1, crucible 2, seed crystal holder 3, and the like are used more frequently herein, the possibility of using other terms is not excluded. These terms are merely used to describe and explain the nature of the present invention more conveniently; construing them as any additional limitation is contrary to the spirit of the present invention.

### LIST OF REFERENCED PARTS

1 furnace
2 crucible
3 seed crystal holder
31 mounting groove
32 lifting shaft
33 first cylinder
34 motor
4 furnace heater
41 first induction heating coil
42 second induction heating coil
43 third induction heating coil
44 fourth induction heating coil
5 heater-cooler device
51 metal tube
52 adjust shaft
53 second cylinder
6 jet pipe
61 dustproof part
62 branch tube
7 preheat canister
71 vapor chamber
72 gas gap
73 preheat channel
74 heat source
75 gas supply tube
76 gas source
77 gas storage tank
8 seed crystal
9 silicon carbide single crystal

What is claimed is:

1. A silicon carbide single crystal manufacturing device, comprising:
a furnace within a furnace heater capable of heating the furnace to form an ambient first temperature gradient in the furnace;
a crucible disposed in the furnace;
a seed crystal holder disposed at an upper portion of the crucible, the seed crystal holder capable of rotating and lifting up and down; and
a heater-cooler device having spirally disposed metal tubes, the heater-cooler device disposed outside the seed crystal holder.

2. The silicon carbide single crystal manufacturing device as claimed in claim 1, wherein the heater-cooler device is capable of forming a second temperature gradient distributed along an axial growth direction of silicon carbide single crystals.

3. The silicon carbide single crystal manufacturing device as claimed in claim 2, wherein the heater-cooler device is an induction heating coil with a frequency of 10 kHz to 50 kHz, and the seed crystal holder is capable of passing through the metal tubes as it is ascending.

4. The silicon carbide single crystal manufacturing device as claimed in claim 2, wherein the second temperature gradient formed by the heater-cooler device along the axial growth direction of the silicon carbide single crystals is increased or decreased within a range of 1° C./mm to 20° C./mm.

5. The silicon carbide single crystal manufacturing device as claimed in claim 1, wherein a distance d between a lower end of the heater-cooler device and a port of the crucible is equal to or greater than 20 cm.

6. The silicon carbide single crystal manufacturing device as claimed in claim 5, wherein the furnace heater comprises a third induction heating coil capable of heating and cooling a region between the lower end of the heater-cooler device and the port of the crucible.

7. The silicon carbide single crystal manufacturing device as claimed in claim 1, further comprising a parameter controller capable of reducing a temperature difference between a central portion and a surrounding portion of seed crystals or of grown silicon carbide crystals, wherein the parameter controller is capable of setting a rotation speed and a lifting speed of the seed crystal holder and is capable of setting a flow rate of the gaseous silicon carbides at a lower end of the heater-cooler device to cause growth surfaces of the grown silicon carbide single crystals to form a radial third temperature gradient.

8. The silicon carbide single crystal manufacturing device as claimed in claim 1, wherein a minimum opening area of the crucible is smaller than a half of a cross-sectional area of an inner cavity of the crucible, and an aspect ratio of a height of the crucible to a diameter of the crucible is greater than 5:1.

9. The silicon carbide single crystal manufacturing device as claimed in claim 1, further comprising a temperature controller capable of controlling the first temperature gradient formed by the furnace heater, wherein the temperature controller is capable of controlling a corresponding temperature of the furnace heater when assuaging a silicon carbide crystal transformation, so that a temperature dropping rate is between 0.5° C./min and 30° C./min.

10. The silicon carbide single crystal manufacturing device as claimed in claim 1, wherein an inner bottom surface of the crucible is connected with a plurality of jet pipes, at an upper end of each of the jet pipes is an umbrella-shaped dustproof part, an outer wall of the jet pipe has a plurality of downwardly inclined branch tubes, the branch tubes are located below the dustproof part, a lower end port of each of the branch tubes is a nozzle, and the jet pipes communicate with a gas source.

11. The silicon carbide single crystal manufacturing device as claimed in claim 10, wherein the furnace is disposed with a preheat canister below the crucible, below the preheat canister is disposed with a heat source capable of heating a bottom of the preheat canister, lower ends of the jet pipes extend outside a bottom surface of the crucible and extend into the preheat canister, and the preheat canister communicates with the gas source.

12. The silicon carbide single crystal manufacturing device as claimed in claim 11, wherein a plurality of vapor chambers are horizontally and fixedly connected in the preheat canister in an axial direction, a preheat channel is formed between the vapor chambers capable of allowing roundabout flowing of gas, an inlet end of the preheat channel is located at the bottom of the preheat canister, and an outlet end of the preheat channel is located at a top of the preheat canister.

13. The silicon carbide single crystal manufacturing device as claimed in claim 12, wherein an edge of each of the vapor chambers is disposed with a gas gap, the gas gaps at two adjacent vapor chambers are respectively located on two opposite sides of an axis of the preheat canister, the gas source communicates with a bottom of an inner cavity of the preheat canister through a gas supply tube, and the jet pipes communicate with a top of the inner cavity of the preheat canister.

14. The silicon carbide single crystal manufacturing device as claimed in claim 13, wherein the gas source comprises a plurality of gas storage tanks, there is a plurality of the gas supply tubes, first ends of the gas supply tubes extend into the furnace and communicate with the preheat canister, and second ends communicate with the gas storage tanks respectively.

15. The silicon carbide single crystal manufacturing device as claimed in claim 1, wherein the seed crystal holder has a disk shape, a lower end surface of the seed crystal holder is disposed with a mounting groove capable of mounting seed crystals, and an upper end surface of the seed crystal holder is shaped as a flat bottom cavity or a downwardly curved concave or an upwardly curved convex.

16. The silicon carbide single crystal manufacturing device as claimed in claim 6, wherein the furnace heater further comprises a first induction heating coil capable of heating the preheat canister, a second induction heating coil capable of heating the crucible, and a fourth induction heating coil capable of heating an upper portion of the furnace where the heater-cooler device is located.
